(19) United States
(12) Patent Application Publication
(10) Pub. No.: US 2009/0020227 A1
(43) Pub. Date: Jan. 22, 2009

(54) Vacuum processing apparatus for semiconductor fabrication apparatus

(76) Inventors: Youji Andou, Kudamatsu (JP); Ryoji Nishio, Kudamatsu (JP); Katsushi Yagi, Shunan (JP); Tadamitsu Kanekiyo, Kudamatsu (JP)

Correspondence Address: MCDERMOTT WILL & EMERY LLP, 600 13TH STREET, N.W., WASHINGTON, DC, 20005-3096, US

(21) Appl. No.: 11/892,665

(22) Filed: Aug. 24, 2007

(30) Foreign Application Priority Data
Jul. 17, 2007 (JP) 2007-185203

(51) Int. Cl. H01L 21/3065

(52) U.S. Cl. 156/345.37; 62/259.2

(57) ABSTRACT

A vacuum processing apparatus includes a vacuum processing chamber, a high-vacuum exhaust pump for exhausting the vacuum processing chamber in vacuum, a low-vacuum exhaust pump connected to the downstream side of the high-vacuum exhaust pump, a lower electrode having mounted thereon a substrate to be processed, and a cooling gas supply unit for supplying the cooling gas between the substrate and the lower electrode. The cooling gas supply unit includes a cooling gas supply system and a cooling gas supply line. The cooling gas supply line is connected, through a first waste gas valve, to a waste gas line for exhausting the cooling gas. The waste gas line is connected just above the high-vacuum exhaust pump through a second waste gas valve, and to the exhaust gas line between the high-vacuum exhaust pump and the low-vacuum exhaust pump through a third waste gas valve.

### BACKGROUND OF THE INVENTION

This invention relates to a vacuum processing apparatus, or in particular, to a vacuum processing apparatus adapted for a semiconductor fabrication apparatus.

A method of fabricating a semiconductor device is widely used in which for the purpose of electrical connection between a transistor formed on a wafer and metal wires and between the metal wires, via holes are formed in a layer insulating film between the upper part of the transistor structure and the wires by dry etching using the plasma, and an electrically conductive material such as Cu is filled in the via holes to form the wires.

The dry etching is a technique in which the etching gas introduced into the vacuum processing chamber is converted into a plasma by the high-frequency power applied from an external source, and reactive radicals or ions generated in the plasma are rendered to react with each other on the wafer thereby to selectively etch a masked film to be processed.

In processing the semiconductor wafer (hereinafter referred to as “the substrate to be processed” or “the object substrate”) with plasma, a method has conventionally been used in which a cooling gas is introduced between the object substrate and a lower electrode on which the object substrate is mounted to cool the object substrate.

An example of the this plasma etching method is explained. As described above, the semiconductor is processed with plasma in such a manner that an etching gas such as a rare gas, a fluorocarbon gas or a nitrogen gas is introduced into a vacuum processing chamber, and after being controlled to a predetermined pressure by a vacuum exhaust system including a variable valve for adjusting the pressure of the vacuum processing chamber, a high-vacuum exhaust pump and a low-vacuum exhaust pump, the high-frequency power is applied to make a plasma of the etching gas. In order to attract the positive ions (hereinafter referred to simply as the ions) in the plasma gas to the object substrate arranged on the lower electrode, the high-frequency power is applied to the object substrate through the lower electrode. Upon application of the high-frequency power to the object substrate, a negative self bias potential is generated on the object substrate. As a result, the ions in the plasma enter the object substrate. The incident ions and the surface substances of the object substrate react physically and chemically with each other thereby to promote the etching process. The application of the high-frequency power to the object substrate for etching increases the internal temperature under the surface of the object substrate with the lapse of the etching time. With the increase in the internal temperature, the chemical reaction specifically changes, thereby posing the problems of a change in uniformity of the etching rate, a change in etching shape and the burning of the photoresist. In order to prevent the temperature increase of the object substrate, the lower electrode is cooled by introducing a cooled refrigerant thereinto thereby to cool the object substrate adsorbed to the lower electrode. In the vacuum processing chamber, however, the object substrate and the lower electrode are thermally insulated by vacuum from each other and the object substrate cannot be sufficiently cooled simply by cooling the lower electrode. In view of this, the cooling efficiency is improved by introducing an inert cooling gas between the object substrate and the lower electrode.

Now, a method of cooling the object substrate is explained more specifically. A groove for introducing the cooling gas is formed in the lower electrode in advance. With the starting of the plasma processing, the cooling gas is introduced into the groove. The object substrate and the lower electrode are adsorbed to each other by the electrostatic adsorption force, and the outer peripheral portion is sealed. Therefore, the cooling gas is substantially prevented from leaking. Normally, the cooled refrigerant flows in the lower electrode and cools the lower electrode. The cooling gas accumulated in the groove cools the lower electrode and controls the temperature of the object substrate.

The sequence for exhausting the cooling gas at the end of the etching process according to the related art is explained with reference to FIG. 2. After completing the etching process, the electric neutralization is started to remove the object substrate 216 from the lower electrode 215. During this neutralization process, the vacuum processing chamber 215 continues to be supplied with the etching gas and the high-frequency power, and still contains the plasma. Before the neutralization process ends, therefore, the cooling gas is required to be exhausted from between the object substrate 216 and the lower electrode 215. The cooling gas between the object substrate 216 and the lower electrode 215 is exhausted into the vacuum processing chamber 200 through a waste gas line 206. Unless the pressure between the object substrate 216 and the lower electrode 215 is reduced sufficiently before depletion of the electrostatic absorption force, the depletion of the electrostatic absorption force would separate the object substrate 216 from the lower electrode 215 under the pressure of the cooling gas and might damage the object substrate 216. To prevent this, the electrostatic absorption force is required to be removed after sufficiently reducing the pressure of the cooling gas by exhausting the cooling gas through a high-vacuum exhaust pump 201 and a low-vacuum exhaust pump 202.

During the normal etching process, the pressure of the cooling gas is set to several kPa or, in the vacuum processing chamber 200, to about several Pa. Under this condition, if the cooling gas existing between the object substrate 216 and the lower electrode 215 is exhaust at a time into the vacuum processing chamber 200, the internal pressure of the vacuum processing chamber 200 would sharply increase. The lower the pressure under which the etching process is executed, the larger the degree to which the interior of the chamber is affected when the cooling gas is exhausted. This sharp pressure change causes a change in the composition of the etching gas and the plasma distribution and gives rise to the problem of charging damage.

The charging damage is defined as any of those various charging phenomena which damages or deteriorates the gate insulating film of the semiconductor substrate during the plasma processing of the semiconductor wafer. The gate insulating film is for controlling the flow of the current in the semiconductor circuit, and once the gate insulating film is destroyed, the particular semiconductor circuit becomes inoperative. It is, therefore, critical to protect the gate insulating film from the charging damage.

In order to avoid the yield reduction due to the charging damage, it is necessary to suppress the transient plasma change such as the change in the plasma distribution or gas composition which is caused by the discharge of the cooling gas into the vacuum processing chamber 200 at the end of the etching process.

### SUMMARY OF THE INVENTION

In the apparatus configuration according to the related art (see, for example, FIG. 1 of JP-A-2002-367965), the cooling gas is exhausted to the neighborhood of the high-vacuum exhaust pump. Normally, the rate at which the pressure of the cooling gas exhausted (hereinafter referred to as the waste gas) propagates in the vacuum processing chamber is higher than the discharge speed of the high-vacuum exhaust pump. For this reason, the cooling gas is discharged just above the high-vacuum exhaust pump. This is, however, still insufficient against a sharp increase in the internal pressure of the vacuum processing chamber. Thus, the cooling gas is dispersed unavoidably in the vacuum processing chamber and the plasma distribution is adversely affected.

The object of this invention is to provide a vacuum processing apparatus, wherein the problems of the change in plasma distribution, the change in gas composition and the charging damage caused by the sharp pressure change in the vacuum processing chamber at the time of discharge of the cooling gas are solved by exhausting the cooling gas into the space between a high-vacuum exhaust pump and a low-vacuum exhaust pump.

According to this invention, there is provided a vacuum processing apparatus including a high-vacuum exhaust pump for exhausting the vacuum processing chamber in vacuum, a low-vacuum exhaust pump connected to the downstream side of the high-vacuum exhaust pump, a lower electrode having mounted thereon a substrate to be processed, and a cooling gas supply means for supplying the cooling gas between the substrate and the lower electrode, wherein the cooling gas supply means includes a cooling gas supply gas line connected, through a first waste gas valve, to a waste gas line for exhausting the cooling gas, and wherein the waste gas line is connected just above the high-vacuum exhaust pump through a second waste gas valve on the one hand and to an exhaust gas line between the high-vacuum exhaust pump and the low-vacuum exhaust pump through a third waste gas valve on the other hand.

Another feature of the invention is that the waste gas line is larger in volume than the cooling gas supply line.

The configuration of the invention described above can suppress the sharp pressure increase in the vacuum processing chamber and solves the various problems including the charging damage.

Other objects, features and advantages of the invention will become apparent from the following description of the embodiments of the invention taken in conjunction with the accompanying drawings.

### BRIEF DESCRIPTION OF THE DRAWINGS

FIG. 1 is a diagram for explaining the cooling gas exhaust sequence according to the invention.

FIG. 2 is a diagram for explaining the cooling gas exhaust sequence according to the related art.

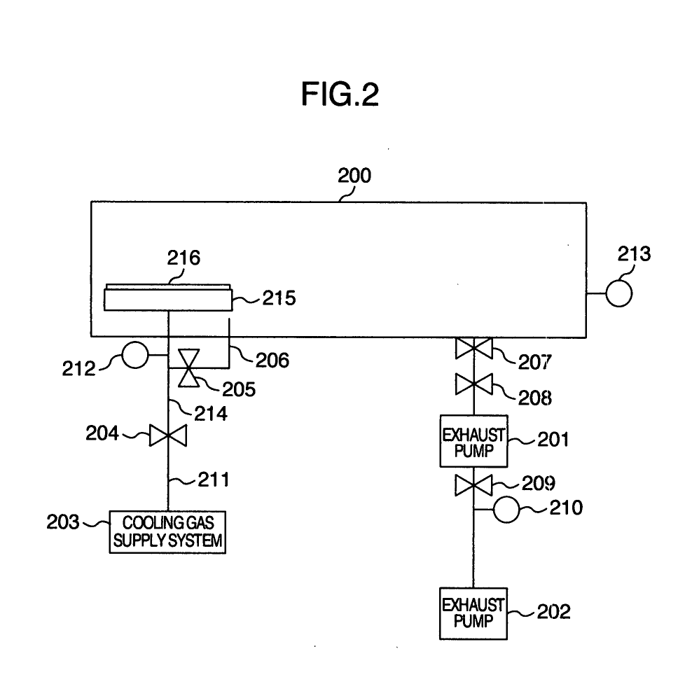

FIG. 3 is a flowchart for explaining a first embodiment.

FIG. 4 is a flowchart for explaining a second embodiment.

### DETAILED EXPLANATION OF THE EMBODIMENTS

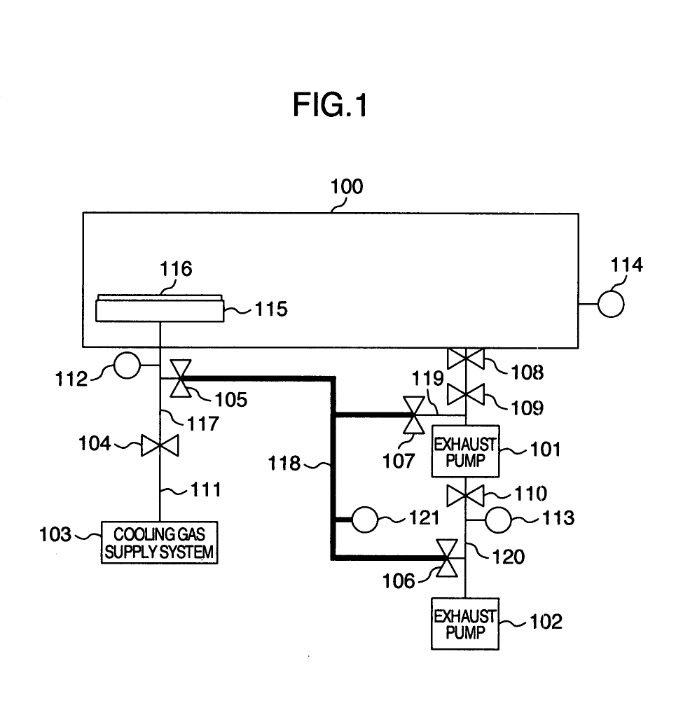

An embodiment of the invention is explained with reference to FIG. 1. The vacuum processing apparatus according to this invention comprises a vacuum processing chamber 100 for executing the etching process. The etching gas is supplied into the vacuum processing chamber 100 by a gas supply system not shown, and converted into a plasma by a high-frequency power supply not shown. The apparatus further comprises a vacuum exhaust system including a variable valve 109 for adjusting the pressure of the vacuum processing chamber 100 to a predetermined level, a high-vacuum exhaust pump 101 and a low-vacuum exhaust pump 102. The low-pressure exhaust pump 102 is assumed to have a sufficiently high exhaust capacity. The apparatus also comprises a lower electrode 115 for mounting the substrate 116 to be processed thereon, a high-frequency power supply, not shown, for introducing the plasma to the lower electrode 115, and a DC power supply for causing the substrate 116 to be adsorbed to the lower electrode 115. The cooling gas is supplied between the object substrate 116 and the lower electrode 115 by a cooling gas supply system 103 and cooling gas supply lines 111, 117. To embody the invention, the apparatus further comprises a waste gas line 118 for exhausting the cooling gas between the high-vacuum exhaust pump 101 and the low-vacuum exhaust pump 102. The pressure between the high-vacuum exhaust pump 101 and the low-vacuum exhaust pump 102 is monitored by a high-vacuum exhaust pump back pressure gauge 113, the pressure of the cooling gas between the object substrate 116 and the lower electrode 115 is monitored by a back surface pressure gauge 112, and the pressure of the waste gas line 118 is monitored by a waste gas line pressure gauge 121. Further, the apparatus comprises a waste gas line 119 for exhausting the cooling gas between the vacuum processing chamber pressure adjusting variable valve 109 and the high-vacuum exhaust pump 101. The waste gas line 118 is assumed to have a sufficiently larger volume than the cooling gas supply line 117 for supplying the cooling gas.

The volume of the waste gas line 118 is determined in such a manner that the back pressure of the high-vacuum exhaust system may not exceed the maximum intake port pressure. During the etching process, the pressure between the object substrate 116 and the lower electrode 115 is normally not higher than 3 kPa. In the case under consideration, however, assume that the back pressure of up to P1 (Pa) is applied. Also, during the etching process, the back pressure of the high-vacuum exhaust system is assumed to be P3 and the pressure of the waste gas line 118 to be P2. Let V1 be the volume of the cooling gas supply line 117, V2 the volume of the waste gas line 118, and V3 the volume of the exhaust gas line 120. Also, let Pmax be the maximum exhaust port pressure of the high-vacuum exhaust system. Then, the volume of the waste gas line 118 is required to satisfy the relation:

V2>{(−Pmax(V1+V3)+P1V1+P3V3)+((Pmax(V1+V3)²)−4(2(Pmax−P2))(PmaxV1V3−P3V1V3))^{1/2}}/(2(Pmax−P2)) (1)

Considering the aforementioned mechanism in which the pressure undergoes a sharp change at the time of exhausting the cooling gas into the vacuum processing chamber 100, the sharp pressure change in the vacuum processing chamber 100 can be suppressed as long as the cooling gas is exhausted under a sufficiently low pressure.

### Embodiment 1

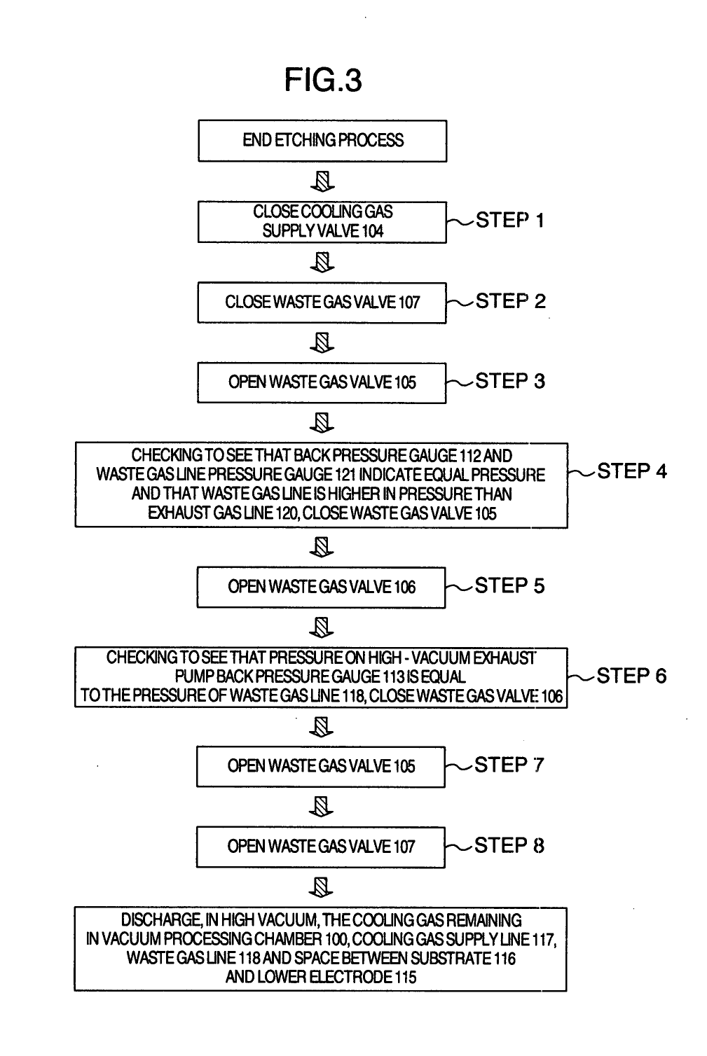

An embodiment of this invention is explained below with reference to FIG. 1 and a flowchart (FIG. 3).

During the normal etching process, the cooling gas supply valve 104 is opened, so that the cooling gas is passed from the cooling gas supply system 103 through the cooling gas supply lines 111 and 117 and supplied between the object substrate 116 and the lower electrode 115. Also, the waste gas valves 105, 106 are closed, while the waste gas valve 107 is opened to exhaust the waste gas lines 118, 119 in high vacuum. As a result, the waste gas lines 118, 119 are reduced in pressure to about the same level as the vacuum processing chamber.

At the end of the etching process, the cooling gas supply valve 104 is closed to shut off the cooling gas supplied from the cooling gas supply system 103 (step 1). Also, the waste gas valve 107 is closed (step 2), while the waste gas valve 105 is opened (step 3), so that the cooling gas pooled between the object substrate 116 and the lower electrode 115 and in the cooling gas supply line 117 is dispersed to the waste gas line 118. Before the end of the etching process, the waste gas line 118 is exhausted in high vacuum, and the pressure is sufficiently low as compared with the back pressure between the object substrate 116 and the lower electrode 115. As a result, the cooling gas is dispersed to the waste gas line 118. After checking to see that the pressure on the back pressure gauge 112 and the pressure on the waste gas line pressure gauge 121 are equal to each other and that the pressure of the waste gas line is higher than that of the high-vacuum exhaust pump back pressure gauge 113, then the waste gas valve 105 is closed (step 4). In order to make sure that the pressure of the waste gas line 118 is lower than the maximum exhaust port pressure Pmax of the high-vacuum exhaust pump, the volume of the waste gas line 118 is required to satisfy Equation (1). Next, the waste gas valve 106 is opened (step 5) and the cooling gas is exhausted between the high-vacuum exhaust pump 101 and the low-vacuum exhaust pump 102. As long as the volume of the waste gas line 118 satisfies Equation (1), the pressure of the high-vacuum exhaust system is not increased to the maximum exhaust port pressure.

The waste gas line 118 is exhausted in vacuum by the low-vacuum exhaust pump 102, and checking to see that the pressure on the high-vacuum exhaust pump back pressure gauge 113 and the pressure on the waste gas line pressure gauge 121 reach the same level, the waste gas valve 106 is closed (step 6). Then, the waste gas valve 105 is opened (step 7), so that the cooling gas remaining in the cooling gas supply line 117 is dispersed to the waste gas line 118. After that, the waste gas valve 107 is opened (step 8). Thus, the cooling gas remaining in the spaces between the vacuum processing chamber 100, the cooling gas supply line 117, the waste gas line 118, the object substrate 116 and the lower electrode 115 is exhausted in vacuum by the high-vacuum exhaust pump 101.

According to this embodiment, the cooling gas is prevented from being exhausted into the vacuum processing chamber 100 by first exhausting the cooling gas between the high-vacuum exhaust pump 101 and the low-vacuum exhaust pump 102. As a result, the sharp increase of the internal pressure of the vacuum processing chamber and the change in gas composition or plasma distribution can be prevented. Also, in view of the fact that the volume of the waste gas line 118 is sufficiently larger than the volume of the space between the cooling gas supply line 117, the object substrate 116 and the lower electrode 115, the back pressure of the high-vacuum exhaust pump 101 can be prevented from being sharply increased.

The waste gas valve 106 is closed, the waste gas valve 107 is opened and the vacuum is created by the high-vacuum exhaust pump 101 and the low-vacuum exhaust pump 102 in order to equalize the pressure between the object substrate 116 and the lower electrode 115 to the pressure in the vacuum processing chamber 100. In the case where the pressure of the cooling gas between the object substrate 116 and the lower electrode 115 is higher than the pressure of the weight of the object substrate 116 and the pressure of the vacuum processing chamber at the timing of stopping the power supply for the electrostatic adsorption force, the object substrate 116 may come off from the lower electrode 115 and the wafer may be destroyed. For this reason, the waste gas valve 106 is closed, the waste gas valve 107 is opened to exhaust the cooling gas to the space between the pressure adjusting variable valve 109 for the vacuum processing chamber 100 and the high-vacuum exhaust pump 101 for high-vacuum exhaustion, so that the pressure between the object substrate 116 and the lower electrode 115 is equalized to the pressure of the vacuum processing chamber 100. By doing so, the object substrate 116 is prevented from coming off from the lower electrode 115. Also, in view of the fact that the cooling gas is exhausted first through the waste gas line 118, and then through the waste gas line 119 just above the high-vacuum exhaust pump 101 by opening the waste gas valve 107, the sharp pressure increase in the vacuum processing chamber due to the cooling gas is suppressed.

### Embodiment 2

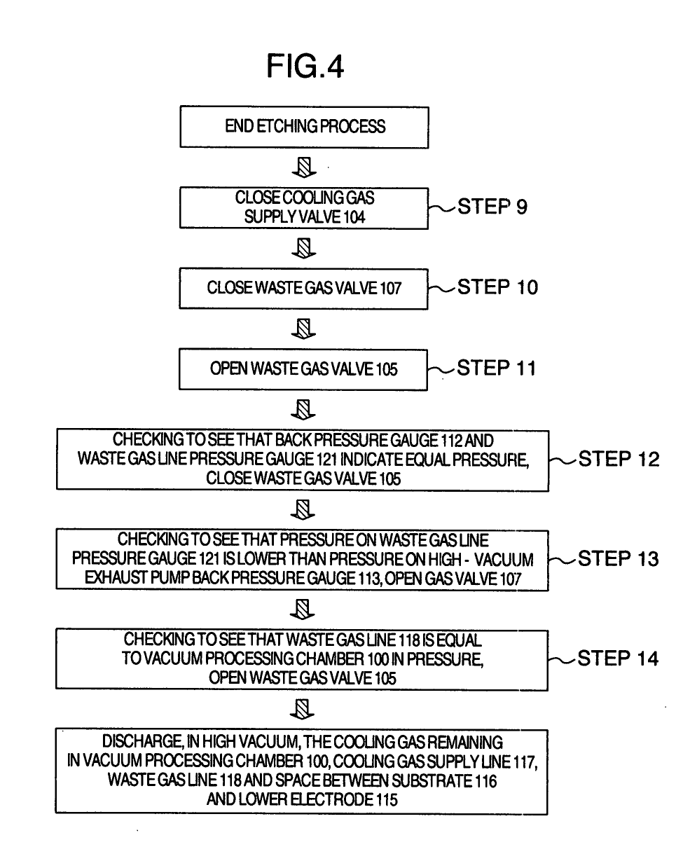

A second embodiment of the invention is explained below with reference to FIG. 1 (diagram for explaining the cooling gas exhaust sequence according to the invention) and FIG. 4 (flowchart).

During the normal etching process, the cooling gas supply valve 104 is opened, so that the cooling gas from the cooling gas supply system 103 is passed through the cooling gas supply lines 111 and 117 and supplied between the object substrate 116 and the lower electrode 115. Also, the waste gas valves 105, 106 are closed, while the waste gas valve 107 is opened to exhaust the waste gas lines 118, 119 in high vacuum. As a result, the pressure of the waste gas lines 118, 119 is reduced to about the same level as the vacuum processing chamber 100.

At the end of the etching process, the cooling gas supply valve 104 is immediately closed to shut off the cooling gas thus far supplied from the cooling gas supply system 103 (step 9). At the same time, the gas valve 107 is closed (step 10). Then, the waste gas valve 105 is opened (step 11), and by checking to see that the back pressure gauge 112 and the waste gas line pressure gauge 121 indicate the same pressure, the waste gas valve 105 is closed (step 12). The cooling gas pooled in the cooling gas supply line 117 is dispersed into the waste gas line 118. Before the end of the etching process, the waste gas line 118 is exhausted in high vacuum and sufficiently lower in pressure than the back pressure between the object substrate 116 and the lower electrode 115. AE a result, the cooling gas is dispersed into the waste gas line 118. After that, by checking to see that the back pressure gauge 112 and the waste gas line pressure gauge 121 indicate the same pressure and that the pressure on the waste gas line pressure gauge 121 is lower than the pressure on the back pressure gauge 113 for the high-vacuum exhaust pump, then the waste gas valve 107 is opened (step 13) thereby to exhaust the waste gas line 118 in high vacuum. In the case where the pressure of the waste gas line 118 is lower than the pressure of the exhaust gas line 120, the exhaust gas would flow back to the waste gas line 118 from the exhaust gas line 120. By checking to see that the pressure of the waste gas line 118 is equal to that of the vacuum pressure chamber 100, therefore, the waste gas valve 105 is opened (step 14) thereby to exhaust the cooling gas remaining in the vacuum processing chamber 100, the waste gas line 118, the cooling gas supply line 117 and the space between the object substrate 116 and the lower electrode 115.

According to this embodiment, the cooling gas is exhausted just above the high-vacuum exhaust pump 101. Since the cooling gas is exhausted after reducing the pressure thereof through the waste gas line 118, however, the vacuum processing chamber 100 is not affected substantially. As a result, the increase in the processing pressure of the vacuum processing chamber, the change in gas composition and the change in plasma distribution are suppressed.

In each of the embodiments described, above, reference numerals 100, 200 designate a vacuum processing chamber, numerals 101, 201 a high-vacuum exhaust pump, numerals 102, 202 a low-vacuum exhaust pump, numerals 103, 203 a cooling gas supply system, numerals 104, 204 a cooling gas supply valve, numerals 105, 106, 107, 205 a waste gas valve, numerals 108, 110, 207, 208 a valve, numerals 109, 209 a pressure-adjusting variable valve for the vacuum processing chamber 100, numeral 111 a cooling gas supply line, numerals 112, 212 a back pressure gauge, numerals 113, 210 a back pressure gauge for the high-vacuum exhaust pump, numerals 114, 213 an internal pressure gauge for the vacuum processing chamber 100, numerals 115, 215 a lower electrode, numerals 116, 216 a substrate to be processed, numerals 117, 211, 214 a cooling gas supply line, numerals 118, 119, 206 a waste gas line, numeral 120 an exhaust gas line, and numeral 121 a waste gas line pressure gauge.

By employing the configuration described above, the sharp pressure increase in the vacuum processing chamber 100 at the end of the etching process can be suppressed, and so can the change in plasma distribution and gas composition and the charging damage.

It should be further understood by those skilled in the art that although the foregoing description has been made on embodiments of the invention, the invention is not limited thereto and various changes and modifications may be made without departing from the spirit of the invention and the scope of the appended claims.

1. A vacuum processing apparatus comprising:
a vacuum processing chamber;
a high-vacuum exhaust pump for exhausting the vacuum processing chamber in vacuum;
a low-vacuum exhaust pump connected to the downstream side of the high-vacuum exhaust pump and a lower electrode having mounted thereon a substrate to be processed; and
a cooling gas supply unit for supplying the cooling gas between the substrate and the lower electrode;
wherein the cooling gas supply unit includes a cooling gas supply system and a cooling gas supply line connected through a first waste gas valve to a waste gas line for exhausting the cooling gas; and
wherein the waste gas line is connected just above the high-vacuum exhaust pump through a second waste gas valve, and also to the exhaust gas line between the high-vacuum exhaust pump and the low-vacuum exhaust pump through a third waste gas valve.

2. The vacuum processing apparatus according to claim 1, wherein the waste gas line has a larger volume than the cooling gas supply line.
